(19) United States
(12) Patent Application Publication
(10) Pub. No.: US 2008/0157304 A1
(43) Pub. Date: Jul. 3, 2008

(54) CHIP PACKAGE STRUCTURE

(75) Inventors: Jie-Hung Chiou, Shanghai (CN); Yong-Chao Qiao, Shanghai (CN); Yan-Yi Wu, Shanghai (CN)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(73) Assignee: ChipMOS Technologies (Bermuda) Ltd., Hamilton HM12 (BM)

(21) Appl. No.: 11/733,782

(22) Filed: Apr. 11, 2007

(30) Foreign Application Priority Data
Dec. 29, 2006 (CN) 200610172822.3

(51) Int. Cl. H01L 23/495

(52) U.S. Cl. 257/676; 257/E23.031

(57) ABSTRACT

A chip package structure including a chip, a lead frame, first bonding wires and second bonding wires is provided. The chip has an active surface, a back surface and bonding pads disposed on the active surface. The lead frame includes a die pad, an insulating layer, transfer bonding pads and inner leads. The back surface of the chip is fixed on the die pad. The insulating layer is disposed on the die pad outside the chip. The transfer bonding pads are disposed on the insulating layer. The first bonding wires are respectively connected to the bonding pads and the transfer bonding pads. The second bonding wires are respectively connected to the transfer bonding pads and the inner leads. The chip package structure has smaller volume and a higher yield rate.

### CROSS-REFERENCE TO RELATED APPLICATION

This application claims the priority benefit of P.R.C. application serial no. 200610172822.3, filed Dec. 29, 2006. All disclosure of the P.R.C. application is incorporated herein by reference.

### BACKGROUND OF THE INVENTION

1. Field of the Invention

The present invention relates to a semiconductor device and a fabricating method thereof. More specifically, the invention relates to a chip package structure and a fabricating method thereof.

2. Description of Related Art

In the industry of the semiconductor, the production of integrated circuits (IC) can be mainly divided into three stages: IC design, IC process and IC package.

During the IC process, a chip is fabricated by the steps such as wafer process, IC formation and wafer sawing. A wafer has an active surface, which generally means the surface that a plurality of active devices is formed thereon. After the IC inside the wafer is completed, a plurality of bonding pads are further disposed on the active surface of the wafer so that the chip formed by wafer sawing can be electrically connected outward to a carrier through the bonding pads. The carrier may be a lead frame or a package substrate. The chip can be connected to the carrier by wire bonding or flip chip bonding, so that the bonding pads on the chip are electrically connected to contacts of the carrier, thereby forming a chip package structure.

FIG. 1A is a schematic cross-sectional side view of a conventional chip package structure. FIG. 1B is a schematic top view of a portion of the members of the chip package structure in FIG. 1A. Referring to both FIGS. 1A and 1B, a conventional chip package structure 100 includes a chip 110, a lead frame 120, a plurality of first bonding wires 130, a plurality of second bonding wires 140, a plurality of third bonding wires 150 and an encapsulant 160. The chip 110 has an active surface 112 and a plurality of first bonding pads 114 and second bonding pads 116 disposed on the active surface 112. The chip 110 is fixed under the lead frame 120. The lead frame 120 includes a plurality of inner leads 122 and a bus bar 124. The inner leads 122 and the bus bar 124 are located over or under the active surface 112 of the chip 110, and the bus bar 124 is ring-shaped.

Referring to FIG. 1B, since the first bonding pads 114 of the chip 110 have the same electric potential, and the first bonding pads 114 may be ground bonding pads or power bonding pads, the first bonding pads 114 having the same electric potential are respectively connected to the bus bar 124 through the first bonding wires 130. The bus bar 124 is further connected to the corresponding inner leads 122 through the second bonding wires 140. However, the bus bar 124 would make the volume of the whole chip package structure 100 larger. Furthermore, the second bonding pads 116 (such as signal bonding pads, whose electric potential fluctuating all the time) of the chip 110 for transmitting signals must be connected respectively to the other corresponding inner leads 122 through the third bonding wires 150. The third bonding wires 150 usually need to cross a portion of the first bonding wires 130, a portion of the second bonding wires 140 and the bus bar 124. Therefore, the length of the third bonding wires 150 is longer, which renders the third bonding wires 150 prone to collapse and thereby causing electric short circuits. Or, the third bonding wires 150 may collapse during the encapsulating process or be pulled apart by the injected encapsulant, thus causing electric open circuits.

### SUMMARY OF THE INVENTION

A chip package structure which reduces the volume of the chip package structure is disclosed in the present invention.

The invention provides a chip package structure to reduce the possibility of collapse of the bonding wires.

In order to solve the aforementioned problem, the invention provides a chip package structure including a chip, a lead frame, a plurality of first bonding wires and a plurality of second bonding wires. The chip has an active surface, a back surface and a plurality of bonding pads disposed on the active surface. The lead frame includes a die pad, an insulating layer, a plurality of transfer bonding pads and a plurality of inner leads. The back surface of the chip is fixed on the die pad. The insulating layer is disposed on the die pad outside the chip. The plurality of transfer bonding pads is disposed on the insulating layer. The plurality of first bonding wires is respectively connected to the bonding pads and the transfer bonding pads. The plurality of second bonding wires is connected respectively to the transfer bonding pads and the inner leads.

In one embodiment of the invention, the insulating layer may be ring-shaped or strip-shaped and disposed on the die pad outside the chip.

In one embodiment of the invention, the insulating layer may be a U-shaped structure disposed on the die pad outside the chip.

In one embodiment of the invention, the chip package structure further includes an encapsulant. The encapsulant encloses the active surface, the die pad, the inner leads, the first bonding wires and the second bonding wires.

Besides the insulating layer in the ring shape, the strip shape or the U-shaped structure, a plurality of insulating pads separated from one another may be used to replace the said insulating layer. The insulating pads are also disposed on the die pad outside the chip, and the transfer bonding pads are respectively disposed on the insulating pads.

In the chip package structure of the invention, the insulating layer disposed on the die pad can be used as the bus bar in the conventional lead frame so that no additional bus bar needs to be disposed on the periphery of the die pad and thereby reduces the overall volume of the chip package structure. Moreover, the bonding pads of the invention are connected respectively to the transfer bonding pads through the first bonding wires. The transfer bonding pads are further connected to the inner leads of the lead frame through the second bonding wires. Hence, the lengths of the first bonding wires and the second bonding wires are shorter. Electric open circuits resulted from the bonding wires collapsing during the encapsulating process or the bonding wires being pulled apart by the injected encapsulant can be thus avoided such that the yield rate of the chip package structure of the invention is raised.

In order to make the aforementioned and other objects, features and advantages of the present invention more comprehensible, preferred embodiments accompanied with figures are described in detail below.

### BRIEF DESCRIPTION OF THE DRAWINGS

FIG. 1A is a schematic cross-sectional side view of a conventional chip package structure.

FIG. 1B is a schematic top view showing a portion of the members of the chip package structure in FIG. 1A.

FIG. 2A is a schematic cross-sectional side view of the chip package structure according to the first embodiment of the invention.

FIG. 2B is a schematic top view showing the lead frame of the chip package structure in FIG. 2A.

FIGS. 3A and 3B are schematic top views showing chip package structures with insulating layers in different shapes.

FIG. 4 is a schematic top view of the chip package according to the second embodiment of the invention.

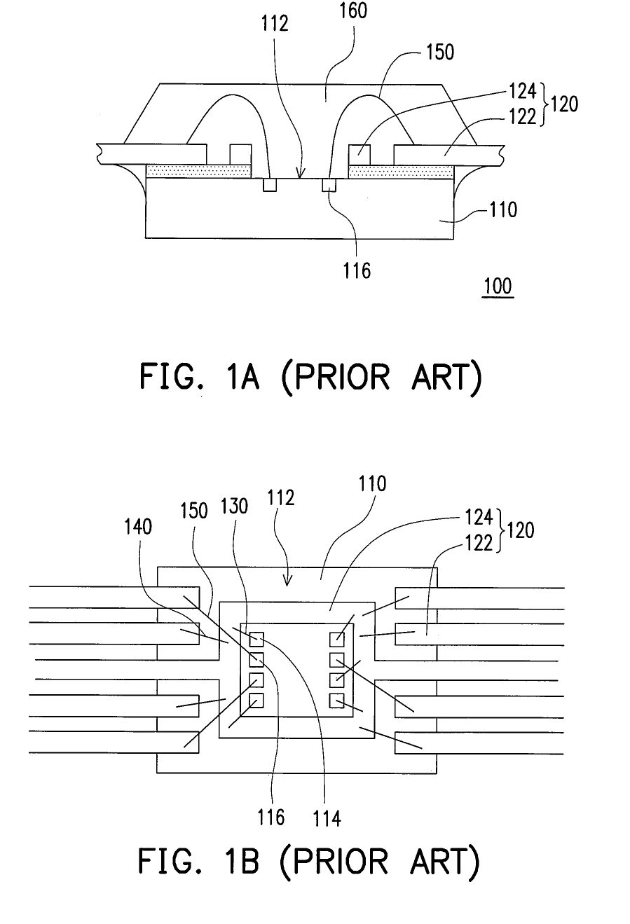

### DESCRIPTION OF EMBODIMENTS

### The First Embodiment

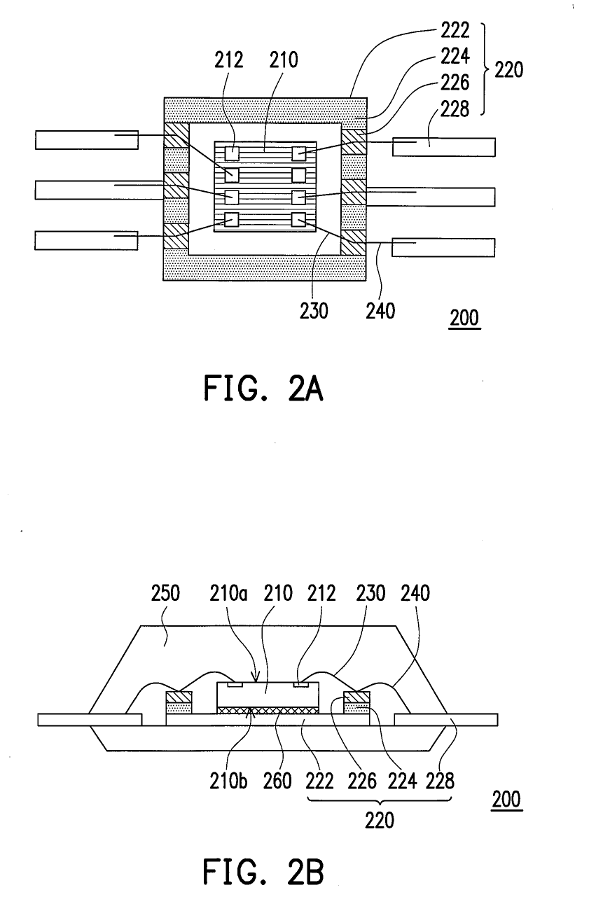

FIG. 2A is a schematic cross-sectional side view of the chip package structure according to the first embodiment of the present invention. FIG. 2B is a schematic top view of the lead frame of the chip package structure in FIG. 2A. Referring to both FIGS. 2A and 2B, a chip package structure 200 of the first embodiment includes a chip 210, a lead frame 220, a plurality of first bonding wires 230 and a plurality of second bonding wires 240. The chip 210 has an active surface 210a, a back surface 210b and a plurality of bonding pads 212. The bonding pads 212 disposed on the active surface 210a of the chip 210 may be ground bonding pads, power bonding pads or signal bonding pads. Additionally, the bonding pads 212 are usually disposed on the edge of the chip 210 so as to facilitate the wire bonding process.

The lead frame 220 includes a die pad 222, an insulating layer 224, a plurality of transfer bonding pads 226 and a plurality of inner leads 228. The back surface 210b of the chip 210 can be fixed on the central area of the die pad 222 with an adhesive 260. The insulating layer 224 is disposed on the die pad 222 outside the chip 210. In the present embodiment, the insulating layer 224 is a ring-shaped structure surrounding the periphery of the chip 210 and keeps a distance from the chip 210 so as to be used as the bus bar of the conventional lead frame. The transfer bonding pads 226 are separately disposed on the insulating layer 224 to remain electrically insulated. In addition, the inner leads 228 surround the periphery of the die pad 222.

The first bonding wires 230 are used to respectively connect the bonding pads 212 with the transfer bonding pads 226. The second bonding wires 240 are used to respectively connect the transfer bonding pads 226 with the inner leads 228. The first bonding wires 230 and the second bonding wires 240 are formed by the wire bonding process. Further, in the present embodiment, the chip package structure 200 further optionally forms an encapsulant 250. The encapsulant 250 encloses the active surface 210a, the die pad 222, the inner leads 228, the first bonding wires 230 and the second bonding wires 240 so that the foregoing elements are prevented from damage or moisture.

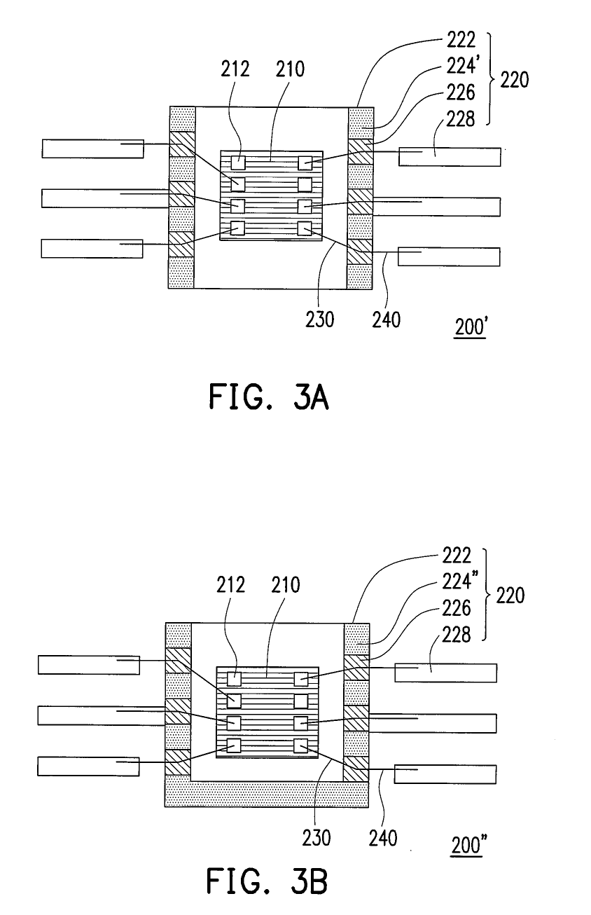

Besides the ring-shaped insulating layer 224 as shown in FIG. 2A, referring to FIG. 3A, in a chip package structure 200′, an insulating layer 224′ are two strip-shaped structures separate from each other and disposed on the die pad 222 outside the chip 210. Also referring to FIG. 3B, an insulating layer 224″ of a chip package structure 200″ is a U-shaped structure disposed on the die pad 222 outside the chip 210. Certainly, other than the shapes shown in FIGS. 2A, 3A and 3B, the insulating layer may also have other shapes. The invention does not limit the insulating layer in this regard.

### The Second Embodiment

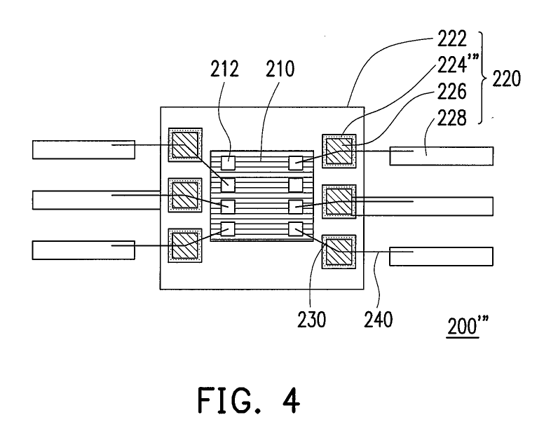

FIG. 4 is a schematic top view of the chip package structure according to the second embodiment of the invention. Referring to FIG. 4, a chip package structure 200′″ has a structure approximately identical to that of the chip package structure 200 in FIG. 2A. The difference between them is that the chip package structure 200′″ has a plurality of insulating pads 224′″ that are separate from one another and the transfer bonding pads 226 are respectively disposed on the insulating pads 224′″. The other elements of the chip package structure 200′″ are approximately identical to those of the chip package structure 200 in FIG. 2A. Thus, they are not to be reiterated herein.

In the chip package structure of the invention, the insulating layer (or insulating pads) and the transfer bonding pads disposed on the die pad are used to integrate the bus bar in the lead frame into the die pad so that the overall volume of the chip package structure is reduced.

Besides, compared with the conventional chip package structure, the bonding pads of the invention are respectively connected to the transfer bonding pads through the first bonding wires. The transfer bonding pads are further connected to the inner leads of the lead frame through the second bonding wires. In other words, the transfer bonding pads function as transfer points for the bonding pads to be electrically connected to the inner leads correspondingly. As the lengths of the first bonding wires and the second bonding wires are shorter, electric open circuits resulted from the bonding wires collapsing during the encapsulating process or the bonding wires being pulled apart by the injected encapsulant can be avoided such that the yield rate of the chip package structure of the invention is raised.

Although the present invention has been disclosed above by the embodiments, they are not intended to limit the present invention. Anybody skilled in the art can make some modifications and alterations without departing from the spirit and scope of the present invention. Therefore, the protecting range of the present invention falls in the appended claims.

What is claimed is:

1. A chip package structure, comprising:
a chip, having an active surface, a back surface and a plurality of bonding pads, wherein the bonding pads are disposed on the active surface;
a lead frame, comprising:
a die pad, the back surface of the chip fixed on the die pad;
an insulating layer, disposed on the die pad outside the chip;
a plurality of transfer bonding pads, disposed on the insulating layer; and
a plurality of inner leads;
a plurality of first bonding wires, respectively connected to the bonding pads and the transfer bonding pads; and
a plurality of second bonding wires, respectively connected to the transfer bonding pads and the inner leads.

2. The chip package structure of claim 1, wherein the insulating layer is ring-shaped and disposed on the die pad outside the chip.

3. The chip package structure of claim 1, wherein the insulating layer is strip-shaped and disposed on the die pad outside the chip.

4. The chip package structure of claim 1, wherein the insulating layer is a U-shaped structure and disposed on the die pad outside the chip.

5. The chip package structure of claim 1, further comprising an encapsulant enclosing the active surface, the die pad, the inner leads, the first bonding wires and the second bonding wires.

6. A chip package structure, comprising:
a chip, having an active surface, a back surface and a plurality of bonding pads, wherein the bonding pads are disposed on the active surface;
a lead frame, comprising:
a die pad, the back surface of the chip fixed on the die pad;
a plurality of insulating pads separated from one another, disposed on the die pad outside the chip;
a plurality of transfer bonding pads, disposed respectively on the insulating pads; and
a plurality of inner leads;
a plurality of first bonding wires, respectively connected to the bonding pads and the transfer bonding pads; and
a plurality of second bonding wires, respectively connected to the transfer bonding pads and the inner leads.

7. The chip package structure of claim 6, further comprising an encapsulant enclosing the active surface, the die pad, the inner leads, the first bonding wires and the second bonding wires.
